(19) United States
(12) Patent Application Publication
(10) Pub. No.: US 2002/0070797 A1
(43) Pub. Date: Jun. 13, 2002

(54) SYSTEM AND METHOD FOR ADJUSTING SEPARATE DEVICES CONCURRENTLY

(76) Inventors: Clifford E. Grey JR., Vicksburg, MS (US); Lewis B. Naron, Tallulah, LA (US); Humphrey M. Barlow, Vicksburg, MS (US)

Correspondence Address: ATTN: CEHEC-OC (Kingman Building), U.S. Army Corps of Engineers, Humhreys Engineer Center, 7701 Telegraph Road, Alexandria, VA, 22315-3860, US

(21) Appl. No.: 09/730,566

(22) Filed: Dec. 7, 2000

(51) Int. Cl. H03G 3/20

(52) U.S. Cl. 330/2; 330/133

(57) ABSTRACT

An apparatus for conditioning an electronic signal that includes a number of signal amplifiers sequentially arranged from a first amplifier to a final amplifier. There is also a microcontroller/microcomputer. A balance circuit is interposed between the first amplifier and the microcontroller/microcomputer, and a calibration step circuit is interposed between the microcontroller/microcomputer and a second amplifier. A digital to analog converter (DAC) is interposed between the microcontroller/microcomputer and each of the amplifiers.

### STATEMENT OF GOVERNMENT INTEREST

The invention described herein may be manufactured and used by or for the Government of the United States of America for governmental purposes without the payment of any royalties thereon or therefor.

### BACKGROUND OF THE INVENTION

1. Field of the Invention

The present invention relates to electronic signal amplification systems and more particularly to means for calibrating electronic signal amplification systems.

2. Brief Description of the Prior Art

For various uses it is necessary to provide a means of converting low level voltage signals from transducers to voltage level signals. In such systems, a means of calibrating the amplifiers must be provided.

U.S. Pat. No. 4,510,454 to Sherman, for example, discloses digitally controlled calibration of amplifiers in which the device refers to a memory for the calibration specification.

U.S. Pat. No. 5,561,395 to Melton et al, discloses an amplifier calibration system that is controlled automatically by a controller that has the specification in storage.

U.S. Pat. No. 5,867,060 to Burkett, Jr. et al, discloses a power delivery system for amplifiers that refers to a memory. The memory is in storage and is addressed from a system controller.

### SUMMARY OF THE INVENTION

The present invention comprises an apparatus for conditioning an electronic signal comprising signal amplifying means; means for inputting a signal into each of the amplifying means; electronic control means; balance means electronically interconnected between the control means and the signal amplifying means; calibration means electronically interconnected between the control means and the signal amplifying means; and digital to analog converter (DAC) means electronically interposed between the control means and the signal amplifying means.

Preferably there will be multiple individual card signal amplifiers, which in a preferred case may be twenty-one, but any number could be employed. The amplifiers do not use balance, calibration, or final gain stage potentiometers. The balance, calibration and final gain control are all done with a microcontroller controlled digital to analog converter (DAC). Two single DAC's which are a balance circuit and a calibration step circuit will control, respectively, the balance and calibration steps for all amplifiers while an amp card level DAC will control the final output gain. The microcontroller is the brain of the unit; allowing control, memory and interfacing to the amp box. A user, through the keypad interface, will be able to load particular calibration values (scaling relations) where the values are stored in flash memory for future use. The calibration values translate the voltage signal into appropriate engineering units. A technician will be able to press one button and all the channels will be zeroed, the calibrations will be turned on and the final output stage gain automatically set to the user level all within seconds, thus reducing the setup time from an hour to mere seconds. Through a preferably 900 MHz transmitter, a user will be able to do all the above remotely. All of the previous levels can be read back from memory, which will allow a field engineer to judge whether a transducer is behaving correctly. A simple data collection routine can be built into the microcontroller run time software allowing a back up means for data collection to the data that is sent real time to an instrumentation van. The data can be transmitted back to a remote location in real time provided the user stays within the limits of the baud transmission rate or the data can be digitized, stored in memory and downloaded after an experiment through a preferably 900 MHz modem.

### BRIEF DESCRIPTION OF THE DRAWINGS

Other objects, features and advantages of the present invention will become apparent upon reference to the following description of the preferred embodiments and to the drawing, wherein corresponding reference characters indicate corresponding parts in the drawing and wherein:

FIG. 1 is a schematic block diagram of a preferred embodiment of the amplifier system of the present invention;

FIG. 2 is a schematic diagram showing one particular preferred amplifier circuit, which may be used in the system shown in FIG. 1; and

FIG. 3 is a software flow chart used in the system shown in FIG. 1.

### DETAILED DESCRIPTION OF THE PREFERRED EMBODIMENT

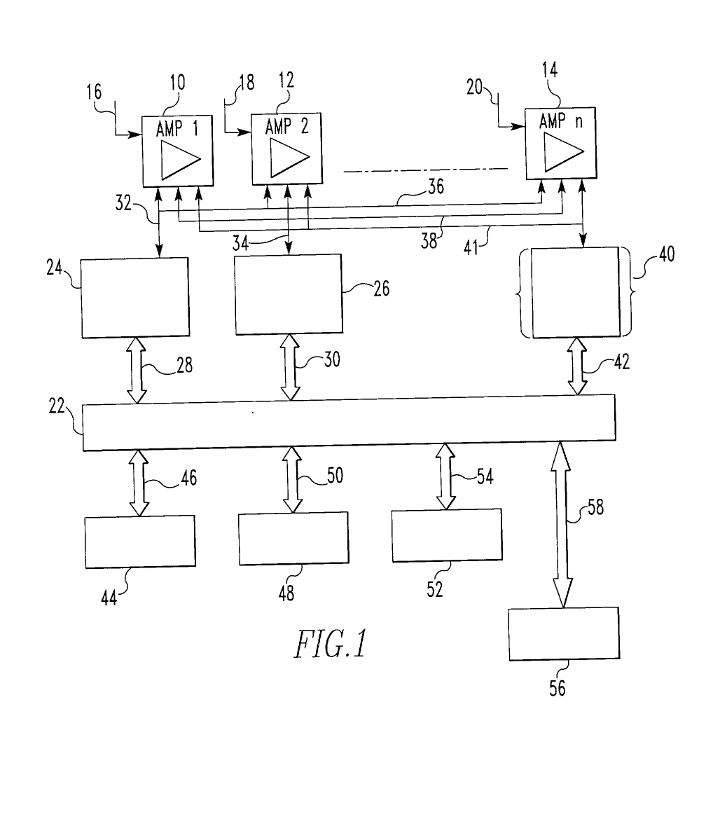

Referring to FIG. 1 the system includes a plurality of amplifiers such as signal amplifier 10 (Amp 1), signal amplifier 12 (Amp 2) and signal amplifier 14 (Amp n). There is a signal input 16 to signal amplifier 10. There is a signal input 18 to signal amplifier 12, and a signal input 20 to signal amplifier 14. The system also includes a microcontroller/microcomputer 22. There is also a balance circuit 24 and a calibration step circuit 26. Between the microcontroller/microcomputer 22 and the balance circuit 24 there is an interconnection 28. Between the microcontroller/microcomputer 22 and the calibration step circuit 26 there is an interconnection 30. Between balance circuit 24 and signal amplifier 10 there is an interconnection 32. Between calibration step circuit 26 and amplifier 12 there is an interconnection 34. Between signal amplifier 10, signal amplifier 12 and signal amplifier 14 there is an interconnection 36. Between signal amplifier 10 and signal amplifier 14 there is an interconnection 38. There is also a DAC 40, which is connected to signal amplifiers 10, 12 and 14 through DAC input 41. The microcontroller/microcomputer 22 is connected to DAC 40 by input 42. Digital controlled final output stage data is inputted from microcontroller/microcomputer 22 through line 41 to signal amplifier 14. The system also includes a 900 MHz modem 44, which is interconnected to the microcontroller/microcomputer 22 by interconnection 46. There is also a LCD display 48, which is interconnected to microcontroller/microcomputer 22 by interconnection 50. There is a numeric keypad 52, which is interconnected to microcontroller/microcomputer 22 by interconnection 54. There is a laptop computer interface 56, which is interconnected to microcontroller/microcomputer 22 by interconnection 58.

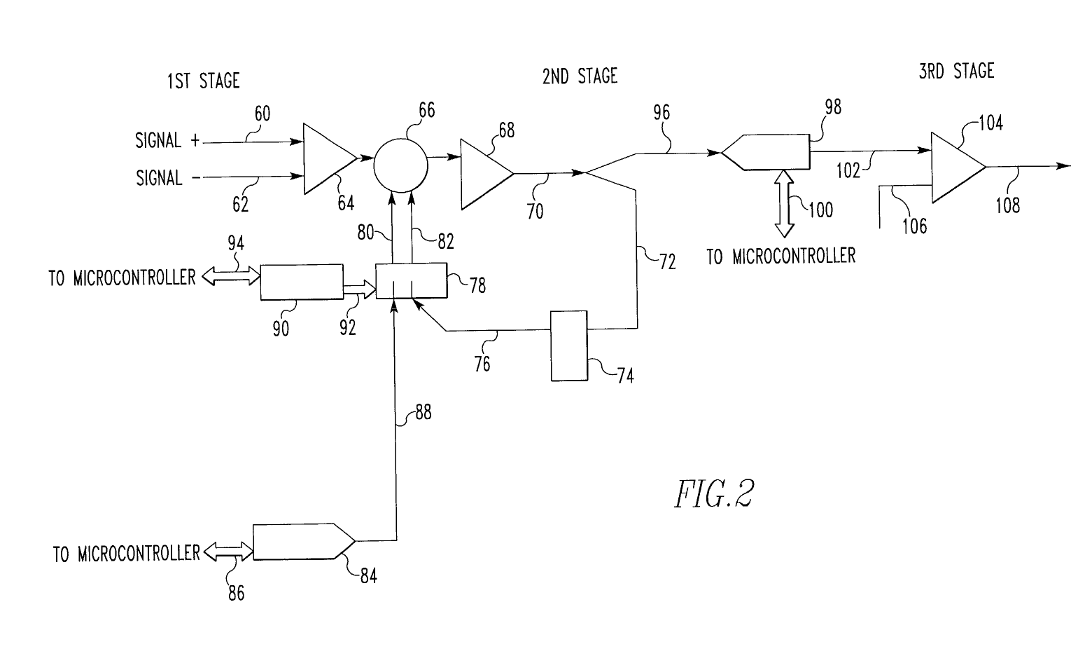

Referring to FIG. 2, a preferred circuit, which may be used in the signal amplifiers 10, 12 and/or 14 is shown. This circuit includes a positive input signal line 60 and an negative input signal line 62 to differential operational amplifier 64. This positive input signal line 60 and negative input signal line 62 correspond respectively to lines 16, 18, and/or 20 for signal amplifiers 10, 12 and 14 respectively. The differential operational amplifier 64 is connected to summing junction 66 which in turn is connected to inverting operational amplifier 68, which is connected by lines 70 and 72 to sample and hold device 74, which is connected by line 76 to digital control switch 78, which inputs to summing junction 66 through lines 80 and 82. There is a calibration circuit 84 which is interconnected to microcontroller/microcomputer 22 by input line 86 and which is connected to the digital control switch 78 through line 88. There is also a shift regulator 90 that is connected to digital control switch 78 through input lines 72 and to the microcontroller/microcomputer 22 through interconnection 94. Line 96 inputs to DAC 98, which produces final gain. DAC 98 is also interconnected to the microcontroller/microcomputer 22 through interconnection 100. Line 102 connects the DAC 98 to an inverting operational amplifier 104 (Amp n) which also receives line 106 and has output line 108. It will be understood that the inputs/outputs to the microcontroller/microcomputer 22 at interconnections 94, 86 and 100 correspond to interconnections 28, 30 and 32 in FIG. 1.

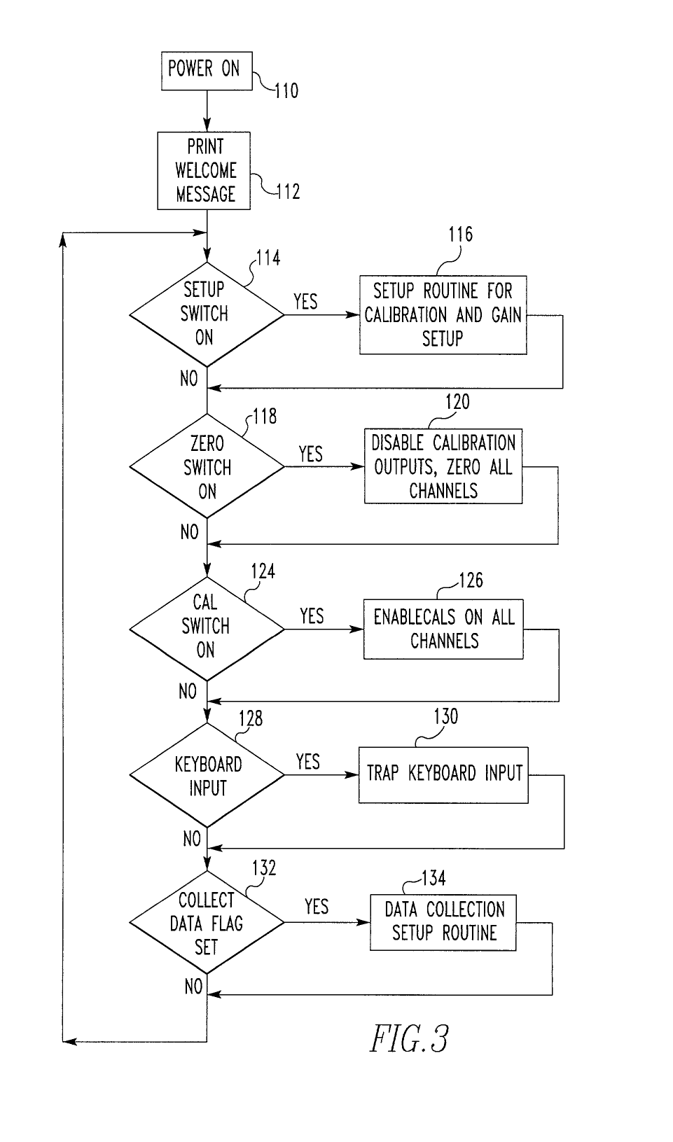

Referring to FIG. 3, in the software flowchart there is a power on 110 followed by a print welcome message 112. There is a setup on switch 114 followed by a setup routine for calibration and gain setup 116. There is then a zero switch on 118 and a disable calibration output to zero all functions 120. There is then a calibration switch on 124 followed by an enable calibration on all channels 126. Next there is a keyboard input 128 followed by a trap keyboard input 130. Finally there is a collected data set 132 followed by a data collection and setup routine 134.

It will be appreciated that the above-described apparatus discloses means for quickly and efficiently calibrating amplification systems.

While the present invention has been described in connection with the preferred embodiments of the various elements, it is to be understood that other similar embodiments may be used or modifications and additions may be made to the present described embodiment for performing the same function of the present invention without deviating therefrom. Therefore, the present invention should not be limited to any single embodiment, but rather construed in breadth and scope in accordance with the recitation of the appended claims.

What is claimed is:

1. A system for conditioning an electronic signal comprising:
signal amplifying means;
means for inputting an electronic signal into the amplifying means;
electronic control means;
balance means electronically interconnected between the control means and the signal amplifying means;
calibration means electronically interconnected between the control means and the signal amplifying means; and
digital to analog converter means electronically interconnected between the control means and the signal amplifying means.

2. The system of claim 1 wherein the signal amplifying means comprise a plurality of amplifiers.

3. The system of claim 1 wherein the electronic control means is a microcontroller/microcomputer.

4. The system of claim 1 wherein the balance means is a balance circuit.

5. The system of claim 1 wherein the calibration means is a calibration step circuit.

6. The system of claim 3 wherein the microcontroller/microcomputer is interconnected with a modem.

7. The system of claim 3 wherein the microcontroller/microcomputer is interconnected with an LCD display.

8. The system of claim 3 wherein the microcontroller/microcomputer has a laptop interface.

9. The system of claim 2 wherein the amplifiers are interconnected from Amp 1 to Amp 2 to Amp n such that Amp 1 is directly connected to Amp 2 and Amp n, Amp 2 is directly connect to Amp 1 and Amp 2, and Amp n is directly connected to Amp 1 and Amp 2.

10. The system of claim 9 wherein the balance means is interposed between the control means and Amp 1.

11. The system of claim 2 wherein the balance means is interposed between the control means and one of the amplifiers.

12. The system of claim 10 wherein the calibration means is interposed between the control means and Amp 2.

13. The system of claim 11 wherein the balance means is interposed between the control means and one of the amplifiers.

14. The system of claim 12 wherein means are provided to input a final output stage gain from the control means to Amp n.

15. The system of claim 13 wherein means are provided to input a final output stage gain from the control means to one of the amplifiers.

16. The system of claim 14 wherein the DAC means is interposed between the control means and Amp 1, Amp 2 and Amp n.

17. The system of claim 15 wherein the DAC means is interposed between the electronic control means and each of said amplifiers.

18. A system for conditioning an electronic signal comprising:
a first, second and third signal amplifier and means for inputting an electronic signal into each of said amplifiers;
electronic control means;
a balance circuit electronically interposed between the first amplifier and the electronic control means;
a calibration step circuit electronically interposed between the second amplifier and the electronic control means;
a digital to analog converter (DAC) electronically interposed between the electronic control means and said first, second and third amplifier.

19. The system of claim 18 wherein means are provided to electronically interconnect the first, second and third amplifiers.

20. A system for conditioning an electronic system comprising:
a plurality of signal amplifiers sequentially arranged from a first amplifier, Amp 1, to a final amplifier, Amp n, wherein there is at least one amplifier, Amp 2, interposed between said amplifiers, Amp 1 and Amp n;
a means for inputting an electronic signal to each of said amplifiers, Amp 1, Amp 2 and Amp n;
a microcontroller/microcomputer;
a balance circuit interconnected with said amplifier, Amp 1, and also interconnected with said microcontroller/microcomputer;
a calibration step circuit interconnected with said amplifier, Amp 2 and also interconnected with said microcontroller/microcomputer; and
a digital to analog converter (DAC) interconnected with each of said amplifiers, Amp 1, Amp 2 and Amp n, and also interconnected with said microcontroller/microcomputer; and
means for interconnecting said amplifier, Amp 1 with said amplifiers, Amp 2 and Amp n, and for interconnecting said amplifier, Amp 2, with said amplifier, Amp n.
